(19) United States
(12) Patent Application Publication
(10) Pub. No.: US 2010/0301951 A1
(43) Pub. Date: Dec. 2, 2010

(54) CURRENT CONTROLLED RING OSCILLATOR AND METHOD FOR CONTROLLING THE SAME

(76) Inventor: Hai Mei XUE, HsinChu (TW)

Correspondence Address: Muncy, Geissler, Olds & Lowe, PLLC, 4000 Legato Road, Suite 310, FAIRFAX, VA, 22033, US

(21) Appl. No.: 12/787,773

(22) Filed: May 26, 2010

(30) Foreign Application Priority Data
May 27, 2009 (TW) 98117704

(51) Int. Cl. H03K 3/03

(52) U.S. Cl. 331/57

(57) ABSTRACT

A current controlled ring oscillator and a method for controlling the same are provided. The current controlled ring oscillator includes a charge pump (CP), a loop filter (LF), a voltage-current (V-I) converter, and an oscillation unit. The CP is used to provide a charging/discharging current. The LF is coupled to the CP, and is used to provide a control voltage. The V-I converter is coupled to the CP, and is used to convert the control voltage to a control current. The oscillation unit includes a plurality of current controlled delay cells serially connected to one another as a ring, and the oscillation unit is coupled to the V-I converter, and controlled by the control current to generate an oscillation signal.

### CROSS-REFERENCES TO RELATED APPLICATIONS

This non-provisional application claims priority under 35 U.S.C. §119(a) on Patent Application No. 98117704 filed in Taiwan, R.O.C. on May 27, 2009, the entire contents of which are hereby incorporated by reference.

### BACKGROUND

1. Technical Field

The disclosure relates to an oscillator, and more particularly to a current controlled ring oscillator and a method for controlling the same.

2. Related Art

Oscillators are widely applied in integrated circuits, and are further a main part of many electronic systems, from a clock of a central processing unit (CPU) to carrier synthesis in a cell phone. In a phase locked loop (PLL), the oscillator is an indispensable part.

Oscillators are mainly classified into two types, namely, inductance-capacitance (LC) oscillators and ring oscillators.

The LC oscillator is an LC loop formed based on a capacitor and an inductor, generates an oscillation through a conversion between an electrical field and a magnetic field, and maintains oscillation through a positive feedback amplifier circuit. The LC oscillator may achieve a high oscillation frequency and low phase noise. However, the LC oscillator design needs passive components that derives the LC oscillator manufactured on the integrated circuit a large area, resulting in a high manufacturing cost.

The ring oscillator is formed by multiple gain stage circuits in a loop, and generates phase change using delays of the gain stage circuits. By serially connecting the multi-stage circuits, the phase change is gradually increased. When a difference between the accumulated phase and an initial phase is π, and a loop gain is greater than 0 dB, the oscillation is completed. The ring oscillator has advantages such as a small area and a wide frequency range. The common ring oscillator is formed by multiple stages of identical delay cells, for example, a common single-end ring oscillator may be a three-stage single-end ring oscillator or a five-stage single-end ring oscillator, and a differential ring oscillator may be a three-stage differential ring oscillator, a four-stage differential ring oscillator, a five-stage differential ring oscillator, and the like. As for a four-stage differential ring oscillator, each stage may generate a phase shift of π/4, and the four-stage differential ring oscillator generates the oscillation if the total gain is enough. The ring oscillator may generate eight-phase non-overlapping clocks, and a phase difference between two neighboring phase clocks is π/4.

Please refer to FIG. 1, a conventional four-stage differential ring oscillator 100 is shown, in which an input frequency is generated by a voltage controlled oscillator (VCO). Charging and discharging of a charge pump (CP) 110 (formed by current sources 111 and 114 and change-over switches 112 and 113) on capacitors of a loop filter (LF) 120 (formed by a resistor R1 and capacitors C1 and C2) are controlled by a phase different between output signals UP and DN of a phase frequency detector (PFD) circuit, and finally a control voltage signal V_{C} is obtained. V_{C} is converted to a required control voltage V_{C}′ by a voltage converting circuit 130 (V_{C}′=k*V_{C}, k may be a constant or a variable, with a unit of 1). Voltage control ends VCO of four-stage differential voltage controlled delay cells 141, 142, 143, and 144 are connected by the V_{C}′ voltage signal, so as to control the output frequency of the ring oscillation unit 140.

FIG. 2 is the voltage controlled delay cell 141 adopted in FIG. 1, in which the voltage controlled delay cell 141 is a latch circuit formed by six transistors (MP1, MP2, MN1, MN2, MR1, and MR2, in which MP1 and MP2 are P type metal oxide semiconductors (PMOS), and the rest are N type metal oxide semiconductors (NMOS)). The action principle is widely known by persons skilled in the art of oscillators, so the description is not given here.

FIG. 3 shows another four-stage differential ring oscillator 200 applying a feed forward structure, in which voltage controlled delay cells 241, 242, 243, and 244 are manufactured based on a latch technique and a pre-charge technique.

However, the ring oscillator of the conventional art still has the problems of phase noise and phase jitter. The problems must be appropriately processed to achieve greater oscillator stability.

### SUMMARY

In view of problems of the conventional art, the disclosure provides a current controlled ring oscillator, which includes a voltage-current (V-I) converter, used to convert a control voltage to a control current; and an oscillation unit, including a plurality of current controlled delay cells serially connected to one another as a ring, and coupled to the V-I converter, in which an oscillation frequency of an oscillation signal generated by the oscillation unit is controlled by the control current.

The disclosure further provides a method for controlling a current controlled ring oscillator, which includes the following steps: providing a control voltage; converting the control voltage to a control current; providing a ring oscillator formed by a plurality of current controlled delay cells; and controlling an oscillation frequency of an oscillation signal generated by the ring oscillator by the control current.

In the current controlled ring oscillator according to the disclosure, the oscillation frequency of the output oscillation signal may be controlled by the current, and problems of phase noise and phase jitter of a conventional ring oscillator may be alleviated through the current controlled delay cells.

### BRIEF DESCRIPTION OF THE DRAWINGS

The disclosure will become more fully understood from the detailed description given herein below for illustration only, and thus are not limitative of the disclosure, and wherein:

FIG. 1 is a first example of a circuit diagram of a voltage control oscillator of a prior art;

FIG. 2 is a circuit diagram of a voltage controlled delay cell in the circuit diagram of FIG. 1;

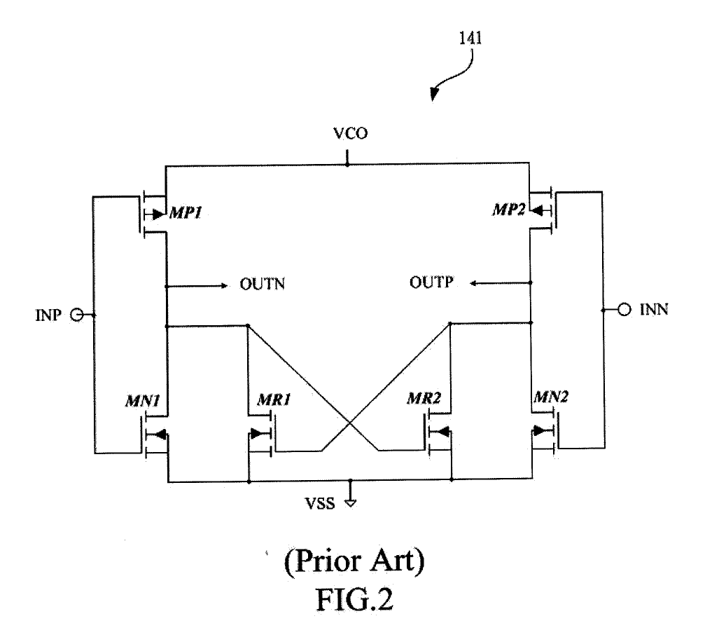

FIG. 3 is a second example of a circuit diagram of a voltage control oscillator of a prior art;

FIG. 4A is a first example of a circuit diagram of a current controlled oscillator according to an embodiment of the disclosure;

FIG. 4B is a circuit diagram of a current controlled delay cell in the circuit diagram of FIG. 4A;

FIG. 5A is a second example of a circuit diagram of a current controlled oscillator according to an embodiment of the disclosure;

FIG. 5B is a circuit diagram of a current controlled delay cell in the circuit diagram of FIG. 5A;

FIG. 6 is a flow chart of a method for controlling a ring oscillator according to an embodiment of the disclosure;

FIG. 7A is a simulation diagram of phase noises generated by an oscillator formed by the voltage controlled delay cells of the conventional art and an oscillator formed by the current controlled delay cells of the disclosure under an oscillation frequency of 5 GHz; and

FIG. 7B is a simulation diagram of phase noises generated by the oscillator formed by the voltage controlled delay cells of the conventional art and the oscillator formed by the current controlled delay cells of the disclosure under an oscillation frequency of 1.25 GHz.

### DETAILED DESCRIPTION

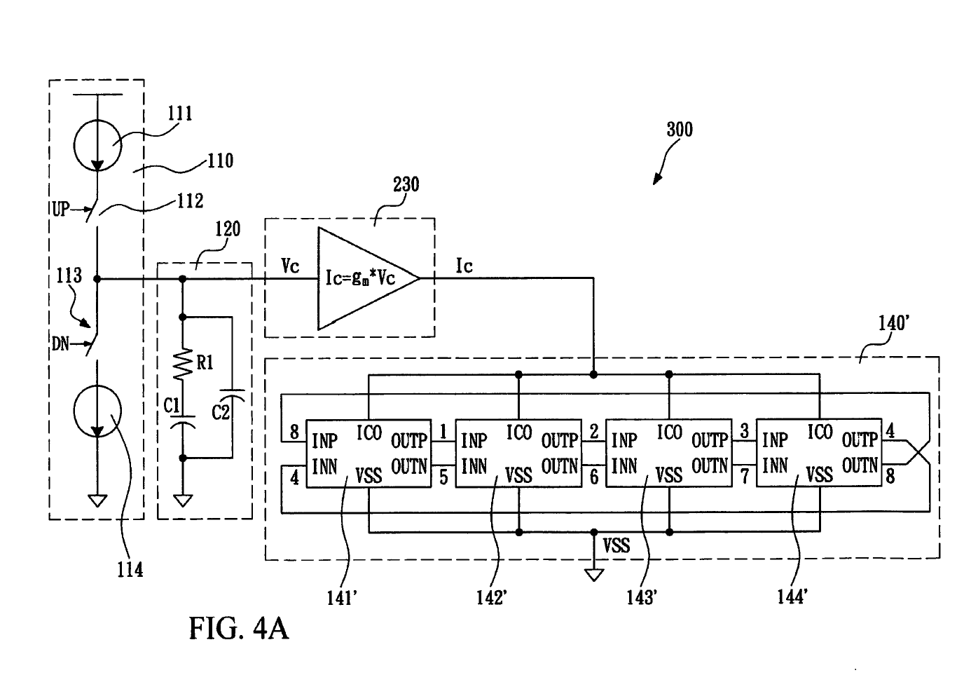

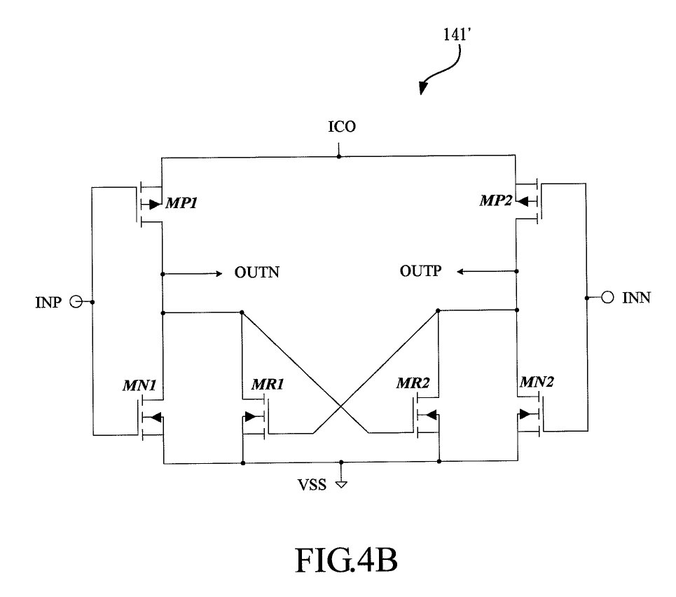

FIG. 4A is a first example of a current controlled ring oscillator according to an embodiment of the disclosure. Please refer to FIG. 4A, in which the current controlled ring oscillator 300 includes a CP 110, used to provide a charging/discharging current; an LF 120, coupled to the CP 110, and used to provide a control voltage Vc; a V-I converter 230, coupled to the CP 110 and the LF 120, and used to convert the control voltage Vc to a control current Ic; and an oscillation unit 140′, including a plurality of current controlled delay cells 141′, 142′, 143′, and 144′ serially connected to one another as a ring, and coupled to the V-I converter 230, in which an oscillation frequency of an oscillation signal generated by the oscillation unit 140′ is controlled by the control current Ic, and the current controlled delay cell here refers to that a current is injected to a power supply end thereof.

For the current controlled delay cells 141′, 142′, 143′, and 144′ in the ring oscillation unit 140′, please refer to a structure of FIG. 4B.

As shown in FIG. 4B, a first transistor MP1 has a source connected to the V-I converter 230 and receiving the control current provided by the V-I converter 230. A second transistor MN1 has a drain connected to a drain of the first transistor MP1 and forming a first output end OUTN, a gate connected to a gate of the first transistor MP1 and forming a first input end INP, and a source connected to a reference voltage Vss. A third transistor MP2 has a source connected to the V-I converter 230 and receiving the control current provided by the V-I converter 230. A fourth transistor MN2 has a drain connected to a drain of the third transistor MP2 and forming a second output end OUTP, a gate connected to a gate of the third transistor MP2 and forming a second input end INN, and a source connected to the reference voltage Vss. A fifth transistor MR1 and a sixth transistor MR2 form a transistor pair, and drains and gates of the fifth transistor MR1 and the sixth transistor MR2 are connected together, in which the drain of the fifth transistor MR1 is connected to the first output end OUTN, the drain of the sixth transistor MR2 is connected to the second output end OUTP, and sources of the fifth transistor MR1 and the sixth transistor MR2 are connected to the reference voltage Vss. It should be noted particularly that the control current Ic generated by the V-I converter 230 may be injected to the power supply ends of the current controlled delay cells 141′, 142′, 143′, and 144′, that is, the sources of the first transistor MP1 and the third transistor MP2.

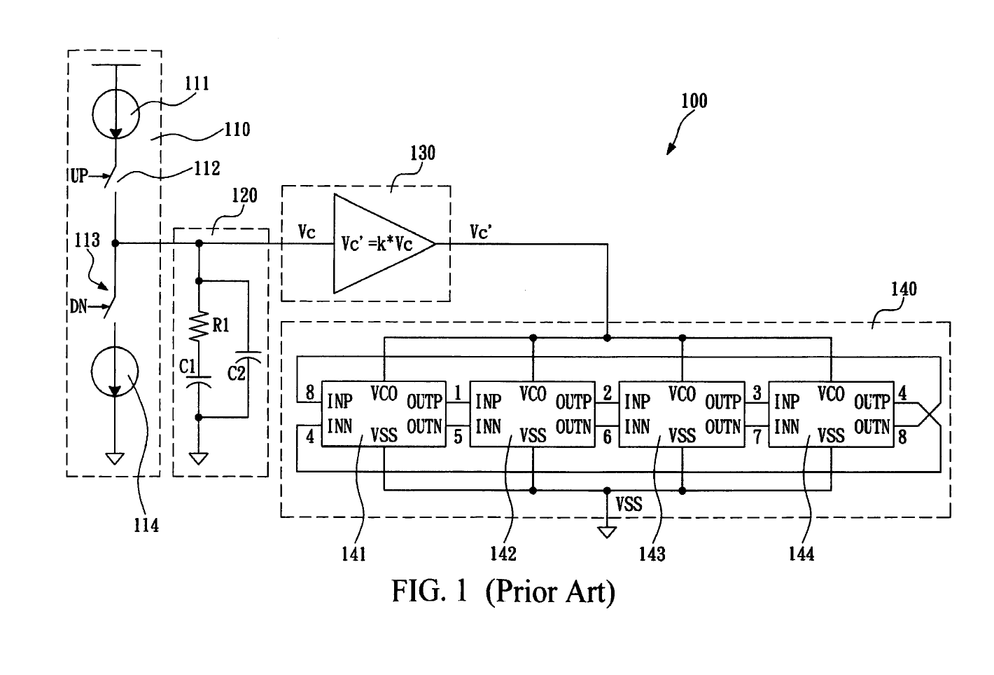

In the current controlled ring oscillator 300, a voltage converter 130 in FIG. 1 is replaced by the V-I converter 230. The V-I converter 230 converts the control voltage Vc to a control current signal I_{C}, in which I_{C}=gₘ*V_{C}, and gₘ, may be a constant or a variable, with a unit of Ampere/Volt (A/V). I_{C} is input to the current controlled input ends of the latch circuits formed by the four-stage differential current controlled delay cells 141′, 142′, 143′, and 144′, thereby controlling an output frequency of the ring oscillation unit 140′.

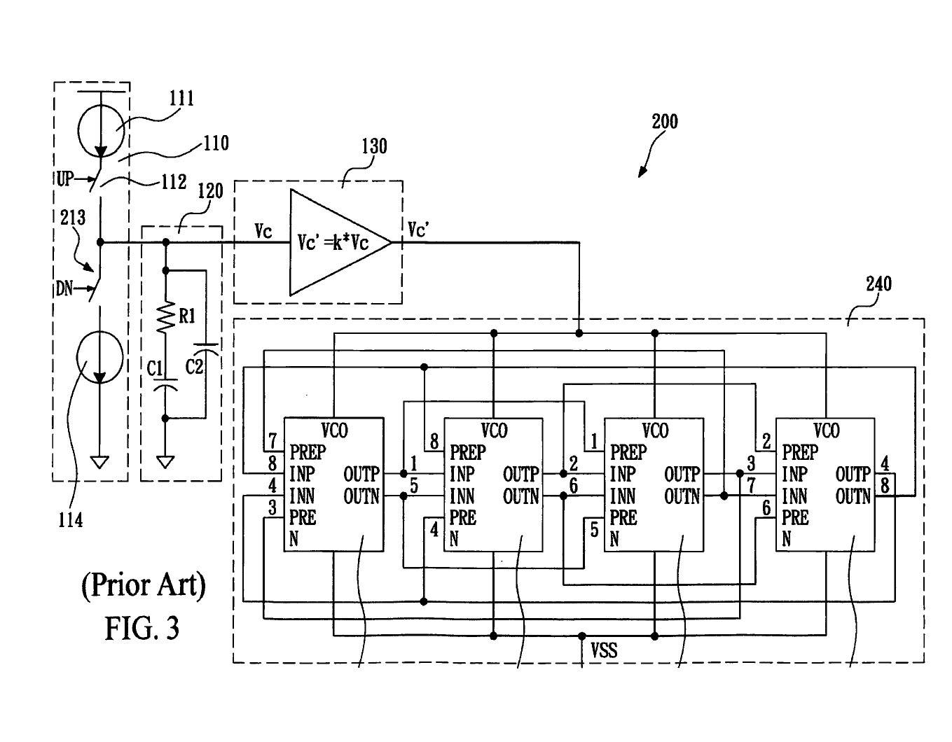

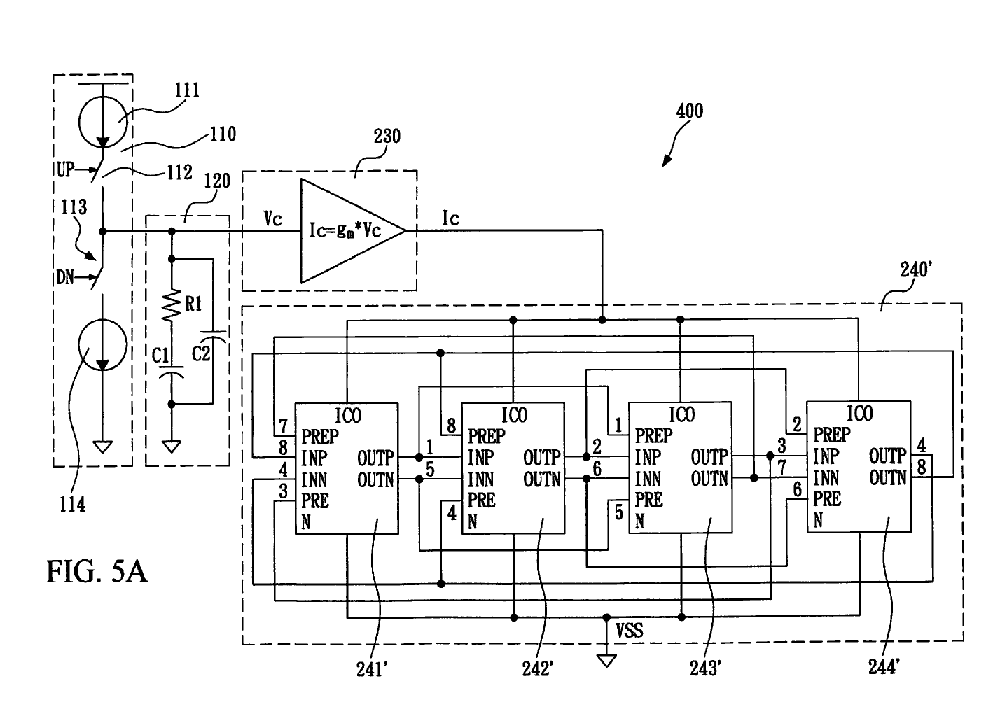

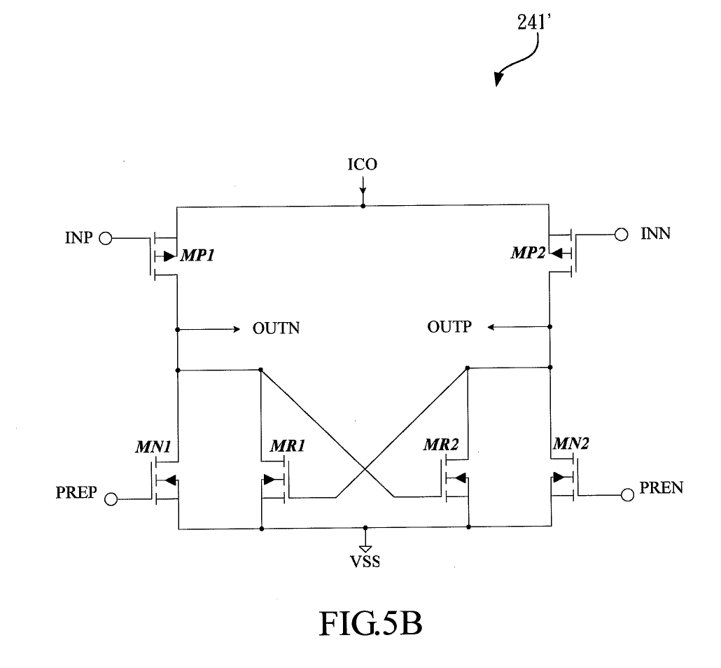

FIG. 5A is a second example of a circuit diagram of a current controlled oscillator according to an embodiment of the disclosure. Please refer to FIG. 5A, in which in the current controlled ring oscillator 400, a voltage converter 130 in FIG. 3 is replaced by a V-I converter 230. The V-I converter 230 converts a control voltage Vc to a control current signal I_{C}, in which I_{C}=gₘ*V_{C}, and gₘ may be a constant or a variable, with a unit of A/V. I_{C} is input to current controlled input ends of latch circuits formed by four-stage differential current controlled delay cells 241′, 242′, 243′, and 244′, thereby controlling an output frequency of a ring oscillation unit 240′.

As shown in FIG. 5B, the structure of the current controlled delay cells 241′, 242′, 243′, and 244′. A first transistor MP1 has a source connected to the V-I converter 230, and a gate forming a first input end INP. A second transistor MN1 has a drain connected to a drain of the first transistor MP1 and forming a first output end OUTN, a gate forming a second input end PREP, and a source connected to a reference voltage Vss. A third transistor MP2 has a source connected to the V-I converter 230, and a gate forming a third input end INN. A fourth transistor MN2 has a drain connected to a drain of the third transistor MP2 and forming a second output end OUTP, a gate forming a fourth input end PREN, and a source connected to the reference voltage Vss. A fifth transistor MR1 and a sixth transistor MR2 form a transistor pair, and drains and gates of the fifth transistor MR1 and the sixth transistor MR2 are connected together, in which the drain of the fifth transistor MR1 is connected to the first output end OUTN, the drain of the sixth transistor MR2 is connected to the second output end OUTP, and sources of the fifth transistor MR1 and the sixth transistor MR2 are connected to the reference voltage Vss. It should be particularly noted that the control current Ic generated by the V-I converter 230 may be injected to the power supply ends of the current controlled delay cells 241′, 242′, 243′, and 244′, that is, the sources of the first transistor MP1 and the third transistor MP2.

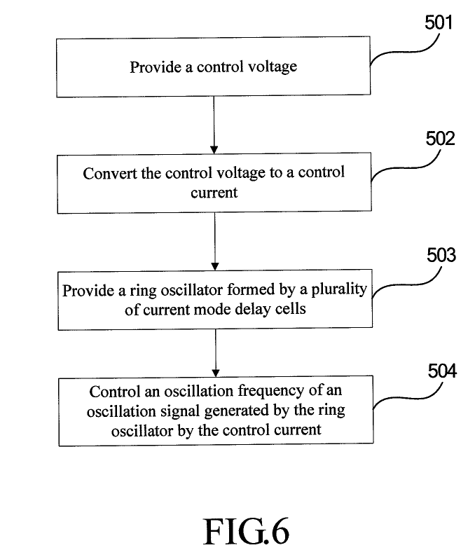

Next, FIG. 6 is a flow chart of a method for controlling a ring oscillator according to an embodiment of the disclosure. Please refer to FIG. 6, in which the method includes the following steps.

In Step 501, a control voltage, that is, a control voltage Vc, is provided.

In Step 502, the control voltage is converted to a control current, that is, the control voltage Vc is converted to a control current Ic. The V-I converter is an example of implementing the step.

In Step 503, a ring oscillator formed by a plurality of current controlled delay cells is provided. For example, the ring oscillator in the example of FIG. 4B or FIG. 5B may be adopted.

In Step 504, an oscillation frequency of an oscillation signal generated by the ring oscillator is controlled by the control current.

In the disclosure, the output frequency of the ring oscillator is controlled by the current, such that the amplitude of an output signal of the ring oscillator is not limited by a control signal, thereby obtaining higher amplitude and a lower phase noise, and eliminating the problem of phase jitter.

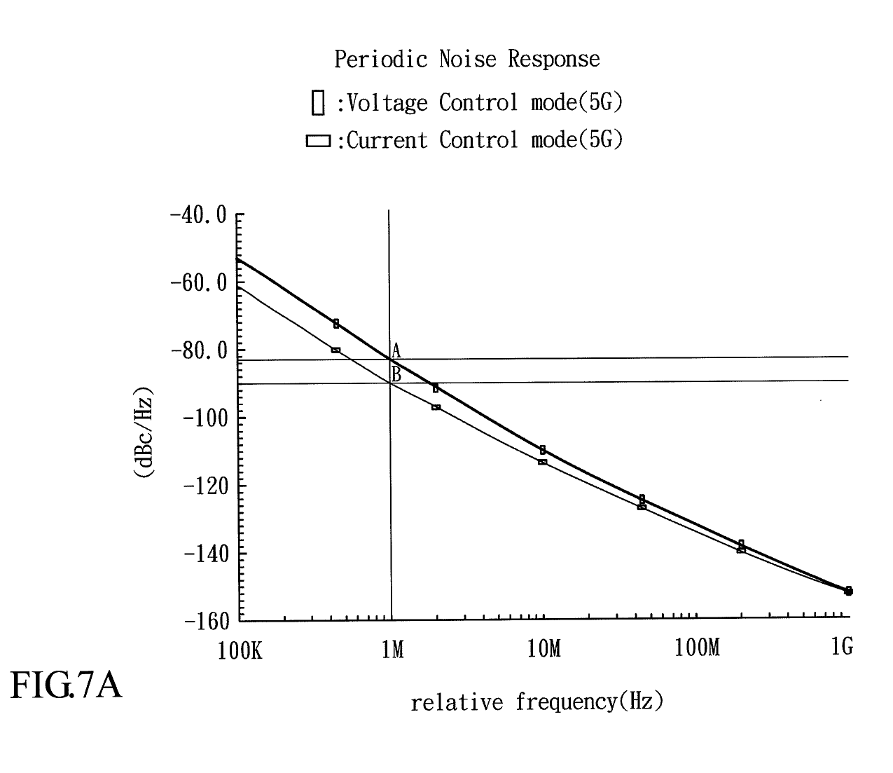

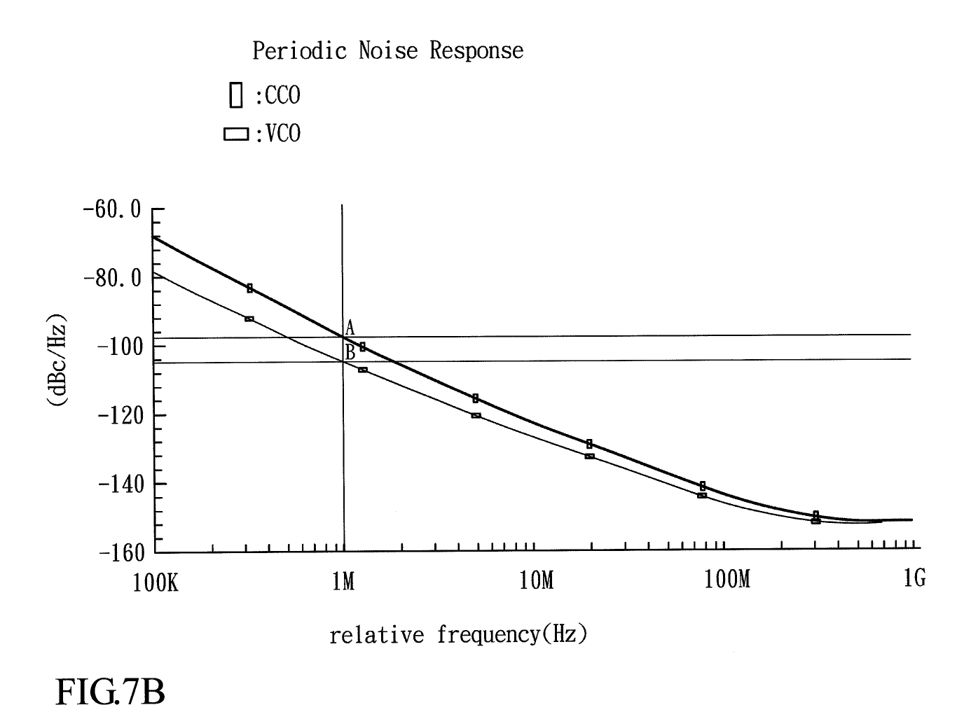

For particular efficacies, please refer to FIGS. 7A and 7B, in which simulation results of the voltage controlled delay cells of the conventional art and the current controlled delay cells of the disclosure under different conditions are described respectively. In FIG. 7A, the control voltage or the control current is adjusted, such that the oscillation frequency generated by the oscillator formed by the voltage controlled delay cells and the oscillation frequency generated by the oscillator formed by the current controlled delay cells are 5 GHZ. It is shown in FIG. 7A that the phase noise (−89.7 dBc/Hz@1 MHz offset), under a current control mode is distinctly lower than the phase noise (−82.9 dBc/Hz@1 MHz offset), under a voltage control mode.

The simulation result under an oscillation frequency of 1.25 GHz is described in FIG. 7B, in which, the phase noise of the oscillator formed by the current controlled delay cells is lower than the phase noise of the oscillator formed by the voltage controlled delay cells.

While the disclosure has been described by the way of example and in terms of the preferred embodiments, it is to be understood that the invention need not to be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A current controlled ring oscillator, comprising:
a voltage-current (V-I) converter, for converting a control voltage to a control current; and
an oscillation unit, comprising a plurality of current controlled delay cells serially connected to one another as a ring, and coupled to the V-I converter, wherein an oscillation frequency of an oscillation signal generated by the oscillation unit is controlled by the control current.

2. The current controlled ring oscillator according to claim 1, further comprising:
a charge pump (CP) and a loop filter (LF) coupled to the charge pump, for providing the control voltage.

3. The current controlled ring oscillator according to claim 1, wherein the current controlled delay cells are latch circuits.

4. The current controlled ring oscillator according to claim 3, wherein the latch circuit comprises:
a first transistor, having a first source connected to the V-I converter;
a second transistor, having a second drain connected to a first drain of the first transistor and forming a first output end, a second gate connected to a first gate of the first transistor and forming a first input end, and a second source connected to a reference voltage;
a third transistor, having a third source connected to the V-I converter;
a fourth transistor, having a fourth drain connected to a third drain of the third transistor and forming a second output end, a fourth gate connected to a third gate of the third transistor and forming a second input end, and a fourth source connected to the reference voltage;
a fifth transistor, having a fifth drain connected to the first output end, a fifth source connected to the reference voltage, and a fifth gate connected to the second output end; and
a sixth transistor, having a sixth drain connected to the second output end, a sixth source connected to the reference voltage, and a sixth gate connected to the first output end.

5. The current controlled ring oscillator according to claim 4, wherein the first transistor and the third transistor are PMOS transistors, and the second transistor, the fourth transistor, the fifth transistor, and the sixth transistor are NMOS transistors.

6. The current controlled ring oscillator according to claim 3, wherein the latch circuit comprises:
a first transistor, having a first source connected to the V-I converter, and a first gate forming a first input end;
a second transistor, having a second drain connected to a first drain of the first transistor and forming a first output end, a second gate forming a second input end, and a second source connected to a reference voltage;
a third transistor, having a third source connected to the V-I converter, and a third gate forming a third input end;
a fourth transistor, having a fourth drain connected to a third drain of the third transistor and forming a second output end, a fourth gate forming a fourth input end, and a fourth source connected to the reference voltage;
a fifth transistor, having a fifth drain connected to the first output end, a fifth source connected to the reference voltage, and a fifth gate connected to the second output end; and
a sixth transistor, having a sixth drain connected to the second output end, a sixth source connected to the reference voltage, and a sixth gate connected to the first output end.

7. The current controlled ring oscillator according to claim 6, wherein the first transistor and the third transistor are PMOS transistors, and the second transistor, the fourth transistor, the fifth transistor, and the sixth transistor are NMOS transistors.

8. A method for controlling a ring oscillator, comprising:
providing a control voltage;
converting the control voltage to a control current;
providing a ring oscillator formed by a plurality of current controlled delay cells; and
controlling an oscillation frequency of an oscillation signal generated by the ring oscillator by the control current.

9. The method according to claim 8, wherein the current controlled delay cell comprises:
a first transistor, having a first source connected to a voltage-current (V-I) converter;
a second transistor, having a second drain connected to a first drain of the first transistor and forming a first output end, a second gate connected to a first gate of the first transistor and forming a first input end, and a second source connected to a reference voltage;
a third transistor, having a third source connected to the V-I converter;
a fourth transistor, having a fourth drain connected to a third drain of the third transistor and forming a second output end, a fourth gate connected to a third gate of the third transistor and forming a second input end, and a fourth source connected to the reference voltage;
a fifth transistor, having a fifth drain connected to the first output end, a fifth source connected to the reference voltage, and a fifth gate connected to the second output end; and
a sixth transistor, having a sixth drain connected to the second output end, a sixth source connected to the reference voltage, and a sixth gate connected to the first output end.

10. The method according to claim 9, wherein the first transistor and the third transistor are PMOS transistors, and the second transistor, the fourth transistor, the fifth transistor, and the sixth transistor are NMOS transistors.

11. The method according to claim 8, wherein the current controlled delay cell comprises:
a first transistor, having a first source connected to a V-I converter, and having a first gate forming a first input end;
a second transistor, having a second drain connected to a first drain of the first transistor and forming a first output end, a second gate forming a second input end, and a second source connected to a reference voltage;
a third transistor, having a third source connected to the V-I converter, and a third gate forming a third input end;
a fourth transistor, having a fourth drain connected to a third drain of the third transistor and forming a second output end, a fourth gate forming a fourth input end, and a fourth source connected to the reference voltage;
a fifth transistor, having a fifth drain connected to the first output end, a fifth source connected to the reference voltage, and a fifth gate connected to the second output end; and
a sixth transistor, having a sixth drain connected to the second output end, a sixth source connected to the reference voltage, and a sixth gate connected to the first output end.

12. The method according to claim 11, wherein the first transistor and the third transistor are PMOS transistors, and the second transistor, the fourth transistor, the fifth transistor, and the sixth transistor are NMOS transistors.

13. A current controlled ring oscillator, comprising:
a plurality of current controlled delay cells, serially connected to one another as a ring, for outputting an oscillation signal; and
a control current source, coupled to the current controlled delay cells, so as to provide a control current and inject the control current to power supply ends of the current controlled delay cells, thereby controlling an oscillation frequency of the oscillation signal.

14. The current controlled ring oscillator according to claim 13, wherein the current controlled delay cells are latch circuits.

15. The current controlled ring oscillator according to claim 14, wherein the latch circuit comprises:
a first transistor, having a first source connected to a voltage-current (V-I) converter;
a second transistor, having a second drain connected to a first drain of the first transistor and forming a first output end, a second gate connected to a first gate of the first transistor and forming a first input end, and a second source connected to a reference voltage;
a third transistor, having a third source connected to the V-I converter;
a fourth transistor, having a fourth drain connected to a third drain of the third transistor and forming a second output end, a fourth gate connected to a third gate of the third transistor and forming a second input end, and a fourth source connected to the reference voltage;
a fifth transistor, having a fifth drain connected to the first output end, a fifth source connected to the reference voltage, and a fifth gate connected to the second output end; and
a sixth transistor, having a sixth drain connected to the second output end, a sixth source connected to the reference voltage, and a sixth gate connected to the first output end.

16. The current controlled ring oscillator according to claim 15, wherein the first transistor and the third transistor are PMOS transistors, and the second transistor, the fourth transistor, the fifth transistor, and the sixth transistor are NMOS transistors.

17. The current controlled ring oscillator according to claim 14, wherein the latch circuit comprises:
a first transistor, having a first source connected to a V-I converter, and a first gate forming a first input end;
a second transistor, having a second drain connected to a first drain of the first transistor and forming a first output end, a second gate forming a second input end, and a second source connected to a reference voltage;
a third transistor, having a third source connected to the V-I converter, and a third gate forming a third input end;
a fourth transistor, having a fourth drain connected to a third drain of the third transistor and forming a second output end, a fourth gate forming a fourth input end, and a fourth source connected to the reference voltage;
a fifth transistor, having a fifth drain connected to the first output end, a fifth source connected to the reference voltage, and a fifth gate connected to the second output end; and
a sixth transistor, having a sixth drain connected to the second output end, a sixth source connected to the reference voltage, and a sixth gate connected to the first output end.

18. The current controlled ring oscillator according to claim 17, wherein the first transistor and the third transistor are PMOS transistors, and the second transistor, the fourth transistor, the fifth transistor, and the sixth transistor are NMOS transistors.
